(19) United States
(12) Patent Application Publication
(10) Pub. No.: US 2025/0132302 A1
(43) Pub. Date: Apr. 24, 2025

(54) HYBRID STACKING OF SEMICONDUCTOR DIES FOR SEMICONDUCTOR DEVICE ASSEMBLY

(71) Applicant: Micron Technology, Inc., Boise, ID (US)

(72) Inventor: Kwun-Han Wu, New Taipei City (TW)

(21) Appl. No.: 18/884,959

(22) Filed: Sep. 13, 2024

Related U.S. Application Data
(63) Continuation of application No. 63/545,482, filed on Oct. 24, 2023.

(51) Int. Cl. H01L 25/18; H01L 21/56; H01L 23/00; H01L 23/31; H10B 80/00

(52) U.S. Cl. CPC H01L 25/18; H01L 21/565; H01L 23/3135; H01L 24/16; H01L 24/29; H01L 24/32; H01L 24/73; H01L 24/81; H01L 24/83; H01L 24/97; H10B 80/00; H01L 2224/16148; H01L 2224/16227; H01L 2224/16238; H01L 2224/2919; H01L 2224/32145; H01L 2224/32225; H01L 2224/73204; H01L 2224/81048; H01L 2224/81815; H01L 2224/83048; H01L 2224/83203; H01L 2224/97; H01L 2225/06513; H01L 2225/06517; H01L 2225/06541; H01L 2924/1431; H01L 2924/3511; H01L 2924/3512

(57) ABSTRACT

A semiconductor device is presented. The semiconductor device includes a lower semiconductor die, a stack of upper semiconductor dies disposed over the lower semiconductor die, a top semiconductor die disposed over the stack of upper semiconductor dies, a non-conductive film material disposed between adjacent semiconductor dies of the lower semiconductor die and the stack of upper semiconductor dies, and a mold compound material disposed between the top semiconductor die and the stack of upper semiconductor dies, and on sidewalls of the stack of upper semiconductor dies and the top semiconductor die.

### CROSS-REFERENCE TO RELATED APPLICATION(S)

The present application claims priority to U.S. Provisional Patent Application No. 63/545,482, filed Oct. 24, 2023, the disclosure of which is incorporated herein by reference in its entirety.

### TECHNICAL FIELD

The present disclosure generally relates to semiconductor devices, and more particularly relates to hybrid stacking of semiconductor dies in semiconductor device assembly.

### BACKGROUND

Semiconductor packages typically include a semiconductor die (e.g., memory chip, microprocessor chip, imager chip) mounted on a substrate or an interface wafer and encased in a protective covering (e.g., an encapsulating material). The semiconductor die may include functional features, such as memory cells, processor circuits, or imager devices, as well as solder pillars electrically connected to the functional features. The process of attaching semiconductor dies on a semiconductor wafer in general refers as chips on wafer (CoW) process, which can increase throughput and reduce difficulties in handling individual semiconductor dies as they continue to shrink in size. Individual semiconductor dies can further be stacked in the semiconductor assemblies.

### BRIEF DESCRIPTION OF THE DRAWINGS

FIG. 1 depicts a cross sectional view of a semiconductor device assembly.

FIG. 2 depicts a cross sectional view of another semiconductor device assembly in accordance with embodiments of the present technology.

FIG. 3 illustrate a flow of forming semiconductor dies for semiconductor device assembly in accordance with embodiments of the present technology.

FIGS. 4A through 4G illustrate stages of forming hybrid stackings for semiconductor device assembly in accordance with embodiments of the present technology.

FIG. 5 is a flow chart illustrating a method of processing semiconductor device assemblies with hybrid stackings in accordance with embodiments of the present technology.

FIG. 6 is a schematic view of a system that includes a semiconductor device configured according to embodiments of the presented technology.

The drawings illustrate only example embodiments and are therefore not to be considered limiting in scope. The elements and features shown in the drawings are not necessarily to scale, emphasis instead being placed upon clearly illustrating the principles of the example embodiments. Additionally, certain dimensions or placements may be exaggerated to help visually convey such principles. In the drawings, the same reference numerals used in different embodiments designate like or corresponding, but not necessarily identical, elements.

### DETAILED DESCRIPTION

CoW assembly is a promising technology for advanced semiconductor device packaging applications. It can be used to overcome the limitations of Wafer-to-Wafer (WoW) bonding and improve die stacking process yield and bonding placement accuracy. CoW assembly can also be adopted for a higher semiconductor device density with reduced package size. For example, in high bandwidth memory (HBM) device fabrication, multiple memory dies (e.g., 4 or 8) can be stacked on top of an interposer die which serves as a communication bridge between the memory dies and a processor. HBM device with stacked memory dies can provide significant higher bandwidth and energy efficiency compared to traditional memory solutions.

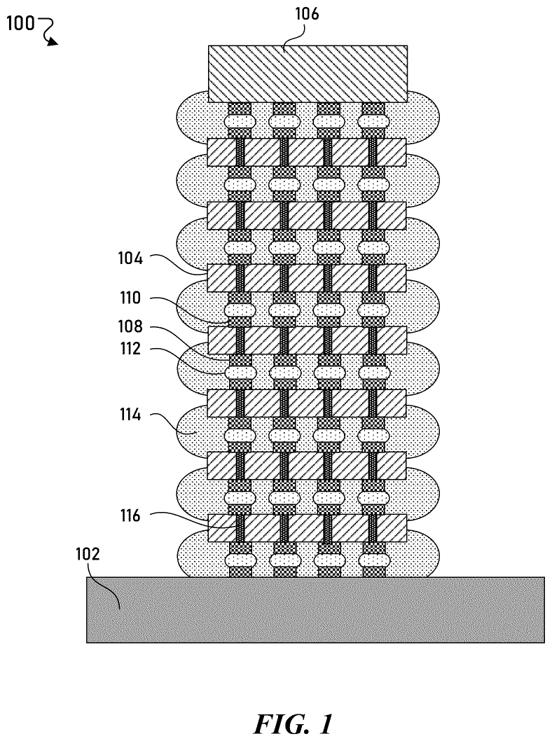

FIG. 1 depicts a cross sectional view of a semiconductor device assembly utilizing the CoW assembly technique. In advanced semiconductor device packaging such as HBM device, semiconductor dies (e.g., memory dies) can be stacked on a substrate wafer. For example, semiconductor dies 104 can be vertically stacked and bonded onto an interposer fabric (IF) die 102, using thermal compression bonding (TCB) technique by applying pressure and heat. Here, the memory die stacks may include a plurality of core memory dies 104 and a top memory die 106 that is disposed above the plurality of core memory dies 104. Each one of the plurality of core memory dies 104 and the top memory die 106 can be interconnected through solder balls 112, solder pillars 108 and solder pads 110. The solder balls 112 can be disposed between corresponding solder pillars 108 and solder pads 110 for electrical interconnection. In this example, each one of the plurality of core memory dies 104 may include multiple through silicon vias (TSV) 116 which provide electrical interconnection between the top memory die 106, the plurality of core memory dies 104, and the IF die 102.

As shown on FIG. 1, non-conductive film (NCF) material 114 can be disposed in the gaps of neighboring memory dies of the memory die stack. The NCF material 114 can also be disposed between a very bottom core memory die and the IF die 102 so as to enhance the adhesion therebetween. Once the NCF material 114 is applied to the semiconductor device assembly 100, the IF die 102 and the memory die stacks can be subjected to pressure and heat in a compression bonding stage, which activates the NCF material 114 to make it soften and adhere to the memory dies and the IF die 102. During the compression bonding and post bonding stages such as cooling and consolidation, the NCF material 114 may inevitably squeeze out of the memory die stacks and the gap between the memory die stacks and the IF die 102.

The semiconductor device assembly 100 illustrate a first example of underfill material in solder based HBM devices, e.g., using NCF material for semiconductor die stacking. This configuration may have semiconductor die alignment issue or NCF material climbing issues. For example, due to a lacking of fiducial mark on its backside surface, the top semiconductor die 106 can not be precisely aligned with the plurality of core memory dies 104 underneath. In addition, besides serving as adhesive to electrically isolate semiconductor dies from the IF wafer or substrate, the NCF material may climb, e.g., onto the sidewall of the plurality of core memory dies 104 in above described example. The NCF climbing may lead to contamination of sensitive components or solder pillars of the semiconductor device assembly 100, and/or obstructing the heat dissipation paths and reducing efficiency of thermal management.

Another example of underfill material in solder based HBM devices is to use mold compound materials. For example, molded underfill (MUF) materials (not shown in FIG. 1) can be applied in the gaps of neighboring memory dies of the memory die stack 104. MUF material can also be disposed between a very bottom core memory die and the IF die 102 to enhance the adhesion therebetween and provide mechanical support. A main concern for using MUF material for semiconductor die stacking in device assemblies is die level warpage. During the stacking of multiple semiconductor dies, a deviation from their original flat shape may happen. Excessive semiconductor die warpage can cause misalignment of the semiconductor dies with the substrate and the substrate, leading to poor interconnection integrity and generating mechanical stresses therein. Semiconductor die warpage related to the MUF process can also lead to the formation of solder joint cracks or voids, causing electrical connection issues and device early failures. Here, the MUF underfill process may also bring in flux residues in the semiconductor device assemble, which is hard to clean. The flux residue may bridge two or more adjacent electrical contacts on the semiconductor dies or the IF wafer, causing reliability issues.

For the semiconductor device assemblies of the present technology, a hybrid stacking using both NCF material and MUF material can be fabricated to overcome above described challenges. In particular, a plurality of semiconductor dies (e.g., core memory dies) disposed in a lower portion of the semiconductor dies stack can be bonded and underfilled using NCF material. Further, a top semiconductor die can be stacked above the plurality of semiconductor dies and underfilled using the MUF material. Utilizing NCF material as underfill material for the core memory dies can eliminate additional mechanical stress applied on the semiconductor die stack and avoid die level warpage. Moreover, applying MUF material as underfill material for the top semiconductor die can significantly improve the top semiconductor die alignment accuracy and prevent NCF material climbing.

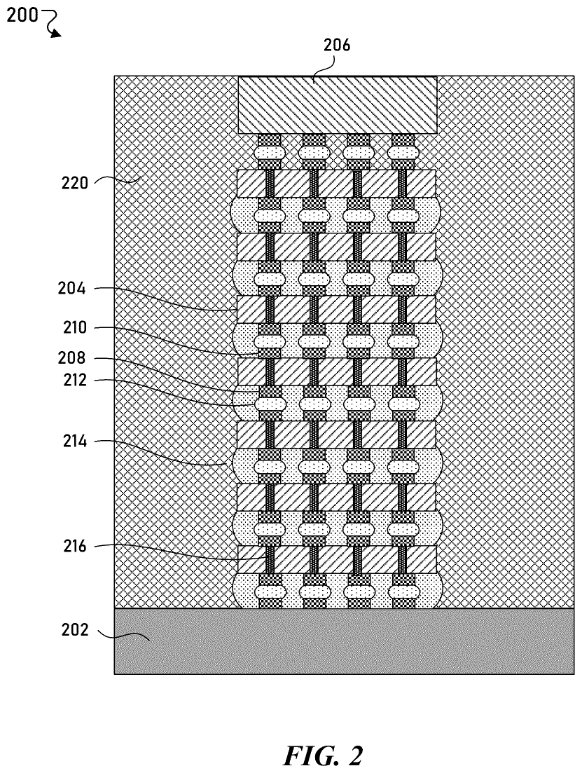

FIG. 2 depicts a cross sectional view of a semiconductor device assembly 200 in accordance with embodiments of the present technology. In this example, multiple semiconductor dies can be vertically stacked above a substrate. Specifically, a plurality of semiconductor dies 204 (such as core memory dies) can be stacked above an IF die 202. Moreover, another top semiconductor die 206 (such as a top memory die) can be further stacked above the plurality of semiconductor dies 204. In this example, NCF materials can be disposed between adjacent semiconductor dies 204. Further, NCF materials can be disposed between the IF die 202 and a lowest semiconductor die 204. Here, NCF materials are applied to provide mechanical support and to enhance the adhesion between semiconductor dies 204 and IF die 202. Each one of the semiconductor dies 204 includes multiple TSVs. In addition, the semiconductor dies 216 and the top semiconductor die 206 are bonded to the IF die 202 through solder pillars 208 and solder pads 210 that are disposed on backside surface of corresponding semiconductor dies 204. The solder pillars 208 and solder pads 210 are electrically connected through corresponding solder balls 212, and further coupled to corresponding TSVs of the semiconductor dies 204 for electrical interconnection. In this example, the NCF material can be made of low viscosity epoxy materials such as epoxy resins that have a thin and runny consistency. In some other examples, the semiconductor device assembly 200 may include a silicon substrate on which the plurality of semiconductor dies 204 and top semiconductor die 206 are stacked.

The semiconductor device assembly 200 also include MUF materials for the vertical semiconductor die stacking. For example and as shown in FIG. 2, MUF material 220 can be applied between the top semiconductor die 206 and the plurality of semiconductor dies 204. The MUF material 220 surrounds the solder pillars and solder balls between the top semiconductor die 206 and the plurality of semiconductor dies 204, fills in the gaps and enhances the adhesion there between. The MUF material may also disposed on sidewalls of the top semiconductor die 206 and the plurality of semiconductor dies 204 to encapsulate the semiconductor device assembly 200 and provide more mechanical support. As shown in FIG. 2, the MUF material 220 can be disposed above a backside surface of the IF die 202. In this example, the MUF material can be made of mold compound materials including an epoxy-based liquid compound with granules, an epoxy-based liquid compound without granules, a granular compound, a thin-film based underfill, a thin-film based compound, a resin-based encapsulant, and/or a polymer.

One unique feature of the semiconductor device assembly 200 shown in FIG. 2 is to use both NCF material and MUF material for stacking of semiconductor dies. For example, NCF material can be used for semiconductor dies 204 underfill in the stacking. Because of the low viscosity property of the NCF material, it is unlikely to cause die level warpage during the stacking. In addition, after the top semiconductor die 206 being bonded on the plurality of semiconductor dies 204, MUF material can be used to underfill the top semiconductor die 206 in assisting the top semiconductor die 206 alignment with underneath plurality of semiconductor dies 204. In particular, a hybrid stacking flow can be implemented to fabricate the semiconductor device assembly 200.

In this example, the semiconductor device assembly 200 can be an eight-high (8H) HBM device including one top memory die and seven core memory dies. In another example, the semiconductor device assembly 200 can be a sixteen-high (16H) HBM device including one top memory die and fifteen core memory dies. In another example, the semiconductor device assembly 200 can be a thirty two-high (32H) HBM device including one top memory die and thirty one core memory dies. In some other examples, the semiconductor device assembly 200 can include multiple stacks of semiconductor dies that are bonded on a logic die. Each one of the multiple semiconductor die stacks can utilize both NCF material and MUF material for semiconductor die underfill.

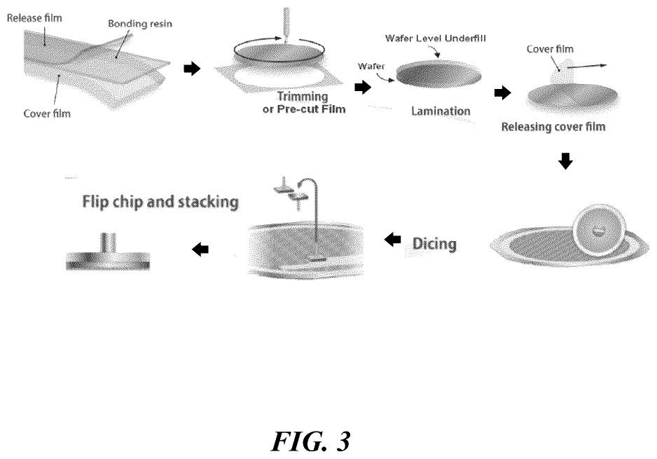

FIG. 3 illustrates stages of forming semiconductor dies for semiconductor device assembly in accordance with embodiments of the present technology. For example, as shown in FIG. 3, a cover film can be coated with a release film through a bonding resin. The cover film can be further trimmed or cut to form a shape matching to corresponding semiconductor wafer. The trimmed cover film and bonding resin can be further laminated on a semiconductor wafer through a wafer level under fill process. In a next step, the cover film can be released from the semiconductor wafer. A semiconductor wafer dicing process can be adopted to dice the semiconductor wafer with NCF material and generate the plurality of semiconductor dies each containing NCF material on its frontside surface. A semiconductor die flip chip and stacking process can be followed to form semiconductor die stacks.

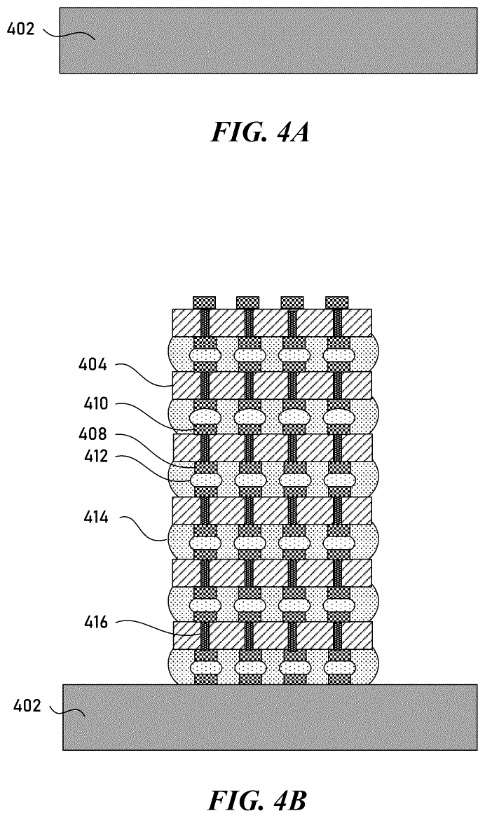

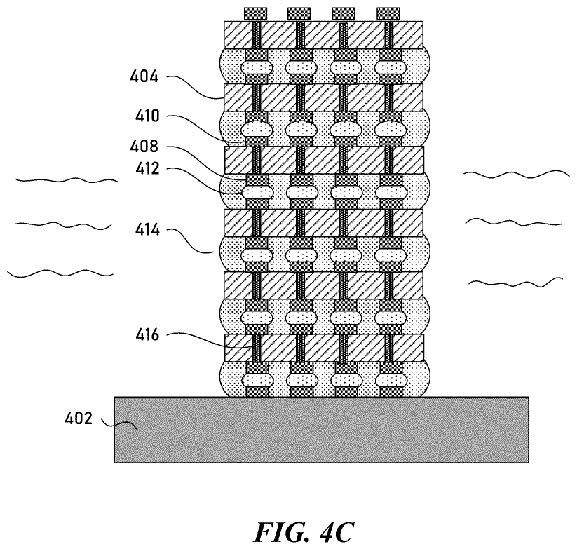

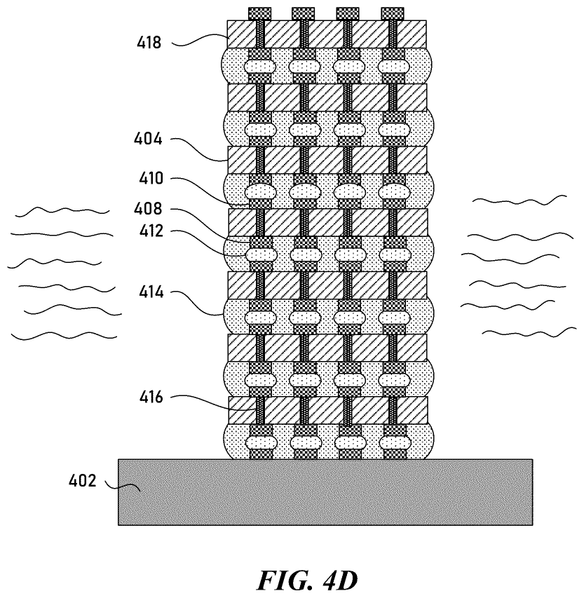

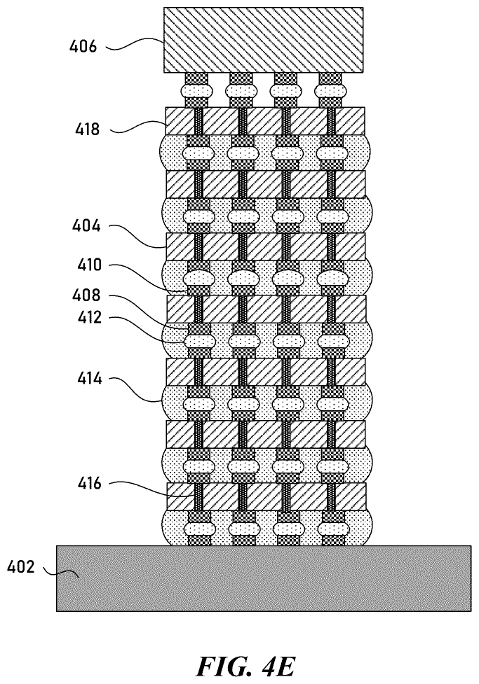

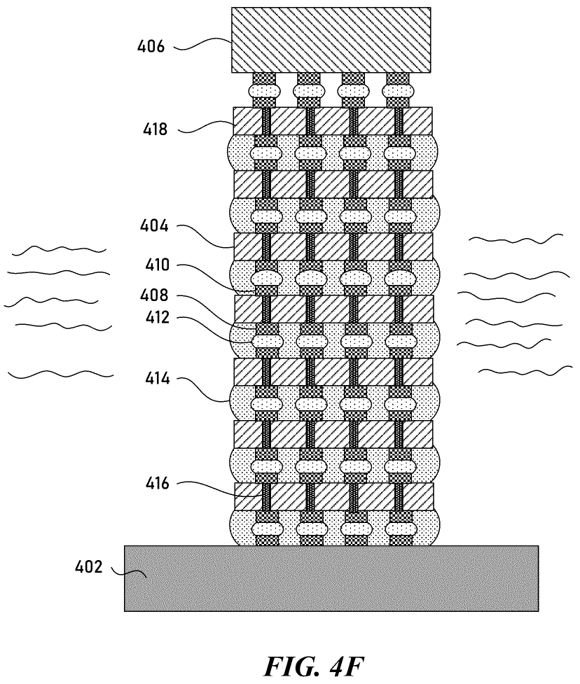

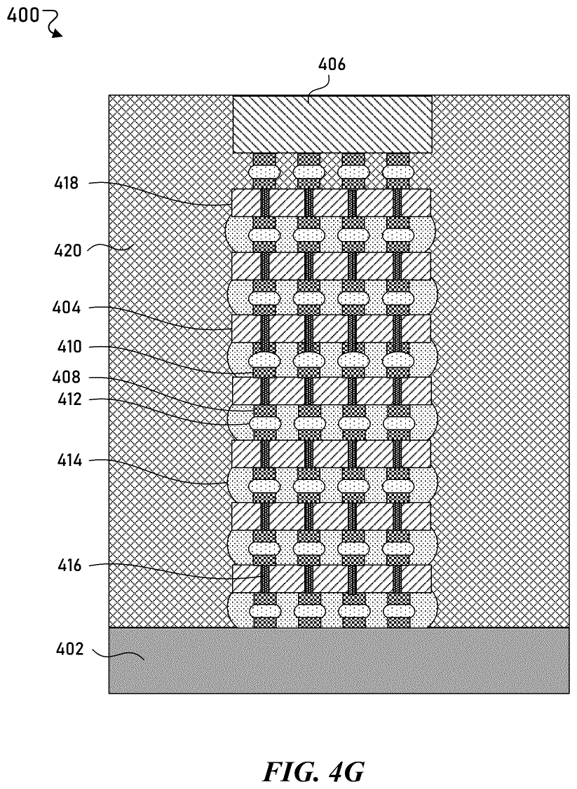

FIGS. 4A through 4G illustrate stages of forming hybrid stackings for semiconductor device assembly 400 in accordance with embodiments of the present technology. The fabrication of the semiconductor device assembly 400 starts from providing a semiconductor wafer 402. The semiconductor wafer can be an IF wafer that may include different types of semiconductor dies (e.g., logic dies, controller dies) than the plurality of semiconductor die stacks included in FIG. 2 (e.g., memory dies, DRAM products). The logic dies of the IF wafer 402 can be configured to exchange electrical signals with the semiconductor dies bonded thereon and with higher level circuitry (e.g., a host device external to the semiconductor device assembly) coupled with the logic dies. In some embodiments, the IF wafer 402 includes interposer dies having various conductive structures (e.g., redistribution layers, vias, interconnects) configured to route electrical signals between the plurality of semiconductor die stacks and higher-level circuitry-e.g., a central processing unit (CPU) coupled with the semiconductor die stacks through the interposer die included in the IF wafer 402. In this example, the IF wafer 402 can be placed frontside down for the downstream hybrid semiconductor dies stacking processes. In another example, the IF wafer 402 may also include solder pillars on its backside surface. In some other examples, the semiconductor wafer 402 can be a silicon wafer.

Turning to a next stage shown on FIG. 4B in which semiconductor dies 404 can be vertically stacked on the semiconductor wafer 402. In this stage, a plurality of semiconductor dies 404 can be bonded on the semiconductor wafer 402. In particular, the plurality of semiconductor dies 404 can be stacked through bonding of solder pillars 408, solder pads 410, and solder balls disposed there between. In this CoW bonding process, the plurality of semiconductor dies 404 can be bonded on the back side surface of the IF wafer 402 through the application of heat and pressure there between. Specifically, the solder pillars of the lowest semiconductor die 404 in the semiconductor die stack can be aligned to and bonded to corresponding solder pillars of the IF wafer 402. The plurality of semiconductor dies 404 can be memory dies. Each one of the semiconductor dies 404 can be a memory core die having a layer 414 of NCF material on its frontside surface. The NCF layer 414 underfills gaps of adjacent semiconductor dies 404 and provides adhesion as well as mechanical support. In this stage, six semiconductor dies 404 can be stacked on the IF wafer 402, targeting an 8H HBM device assembly shown on the end of the flow. The layer 414 of NCF material may be made of epoxy-based materials such as low viscosity epoxy material, acrylic-based materials, and/or polyimide-based materials.

During the stacking of each semiconductor die 404 and after the stacking of plurality of semiconductor dies, an intermediate thermal treatment can be applied on the semiconductor device assembly 400 to lightly cure the NCF material layer 414. As shown in FIG. 4C, the intermediate thermal treatment can be performed at around 140° C. for one second to two seconds. This intermediate thermal treatment can cure the as-deposited NCF material for a better electrical insulation, preventing the risk of short circuits or electrical interference within the packaging. In some other examples, the intermediate thermal treatment process can be performed at different temperature and for various time periods.

Turning now to a next stage in which an upper semiconductor die 418, alongside the NCF layer 414 disposed on its frontside surface, can be stacked above the plurality of semiconductor dies 404. As shown in FIG. 4D, the upper semiconductor die 418 is frontside down and can be identical to each one of the semiconductor dies 404. In addition, the upper semiconductor die 418 can be bonded to the stack of semiconductor dies 404 through collectively bonding of the solder pillars and solder balls. Various technologies including microbump bonding, solder reflow, or TCB can be applied here to stack the upper semiconductor die 418. The interconnections between the upper semiconductor die 418 and underneath plurality of semiconductor dies 404 can be achieved through fine pitch microbumps or TSVs included in semiconductor dies 404 and 418. In this stage, a TCB thermal treatment can be conducted on the semiconductor device assembly 400. For example, the TCB thermal treatment can be performed at a temperature ranging from 330° C. to 380° C. for ten seconds to twenty seconds, to cure the NCF layers 414 included in the stacking process. In some other examples, the TCB thermal treatment process can be performed at different temperature and for various time periods.

In a next stage, a top semiconductor die 406 can be stacked above the upper semiconductor die 418. As shown in FIG. 4E, the top semiconductor die 406 can be thicker than the upper semiconductor die 418 and the semiconductor dies 404 disposed underneath. Here, the top semiconductor die 406 can be frontside down and coupled to the upper memory die 418 through the corresponding solder pillars and solder balls. Alternatively, solder bumps of the top semiconductor die 406 can be aligned with and attached to corresponding contact pads of the upper semiconductor die 418 for a solder-solder bonding. In this example, a flux-less TCB process can be performed to attach the top semiconductor die 406 above the upper semiconductor die 418. For example, direct metal-to-metal bonding can be achieved between solder pillars of the top and upper semiconductor dies 406 and 418, relying on an application of pressure, heat, and time to create a reliable and strong bonding. The absence of flux in this stage means not only no additional material is introduced, but also simplified process and equipment, and improved long-term reliability performance. Notably, in this stage, the top semiconductor die 406 does not come along a layer of NCF material. There are air gaps surround the solder pillars bonds between the top semiconductor die 406 and upper semiconductor die 418.

After the top semiconductor die 406 is stacked, a mass reflow process will be conducted as shown in FIG. 4F. In this stage, the mass reflow can help self-aligning the top semiconductor die 406 to the upper semiconductor die 418. In addition, the high temperature treatment can further cure the NCF material and solder balls included in the semiconductor device assembly 400. Here, the mass reflow process can be conducted at around 260° C. for about 10 minutes. In some other examples, the mass reflow process can be performed at different temperature and for various time periods.

In a next stage, as shown in FIG. 4G, MUF materials can be flowed into the semiconductor device assembly 400. Specifically, MUF materials 420 can be flow into the air gaps between the top semiconductor die 406 and the upper semiconductor die 418. The MUF material can surround the solder pillars and solder balls that are disposed in the air gap to provide mechanical support and enhance the adhesion between the top semiconductor die 406 and the upper semiconductor die 418. Further, the MUF material 420 may overflow, e.g., to encapsulate the sidewalls of the top semiconductor die 406, the upper semiconductor die 418, and the plurality of semiconductor dies 404. In addition, the MUF material 420 can encapsulate the backside surface of the semiconductor wafer 402. In this example, the MUF material 420 can be made of materials including an epoxy-based liquid compound with granules, an epoxy-based liquid compound without granules, a granular compound, a thin-film based underfill, a thin-film based compound, a resin-based encapsulant, and/or a polymer. The flux-less TCB bonding process, mass reflow process, and mold compound flowing process included in above described later stages could enhance the top semiconductor die 406 alignment accuracy because of the intrinsic property of solder materials.

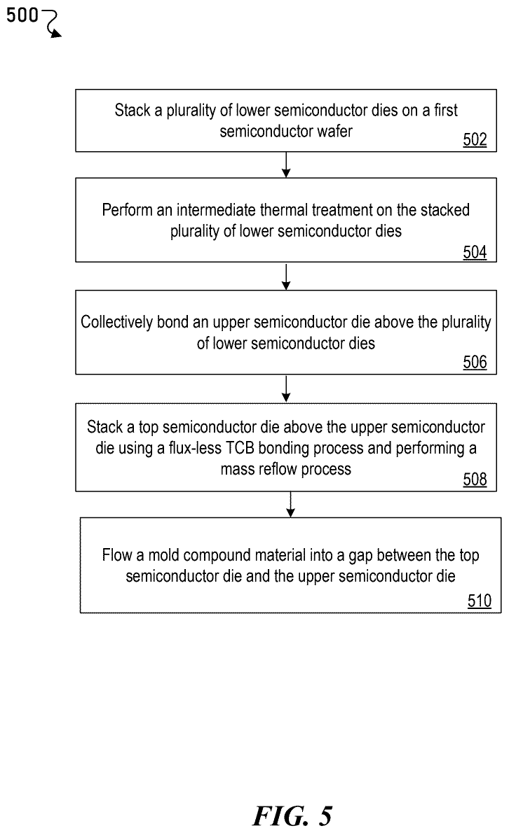

Turning now to FIG. 5 which is a flow chart illustrating a method 500 of processing semiconductor device assemblies with hybrid stackings in accordance with embodiments of the present technology. The method 500 includes stacking a plurality of lower semiconductor dies on a first semiconductor wafer, at 502. For example, a plurality of semiconductor dies 404 can be vertically stacked on the IF wafer 402. Each adjacent semiconductor dies 404 can be bonded through solder pillars and solder balls. In addition, each one of the plurality of semiconductor dies 404 can have a layer 414 of NCF material disposed on its frontside surface, as shown in FIG. 4B.

The method 500 also includes performing an intermediate thermal treatment on the stacked plurality of lower semiconductor dies, at 504. For example, once the plurality of semiconductor dies 404 are stacked on the IF wafer 402, the intermediate thermal treatment can be performed at around 140° C. for one second to two seconds, as described on FIG. 4C. This intermediate treatment can trigger to slightly cure the as-deposited NCF material for a better electrical insulation and stronger mechanical strength in the following fully curing step.

In addition, the method 500 includes collectively bonding an upper semiconductor die above the plurality of lower semiconductor dies through performing a thermal compression bonding (TCB) treatment on the upper semiconductor die and the plurality of lower semiconductor dies, at 506. For example, the upper semiconductor die 418 can be further stacked on the plurality of semiconductor dies 404. As shown in FIG. 4D, the upper semiconductor die 418 includes a layer 414 of NCF material on its frontside surface and electrically connected to the plurality of semiconductor dies 404 through interconnections of TSVs, solder pillars, and solder balls.

The method 500 also includes stacking a top semiconductor die above the upper semiconductor die using a flux-less TCB bonding process and performing a mass reflow process, at 508. For example, the top semiconductor die 406 can be stacked above the upper semiconductor die 418 using a flux-less TCB bonding process, as shown in FIG. 4E. The top semiconductor die 406 can be frontside down and coupled to the upper memory die 418 through the corresponding solder pillars and solder balls. There are only metal-to-metal bonds between the top and upper semiconductor dies 420 and 418, and not NCF materials are disposed therebetween. In addition, as shown in FIG. 4F, the mass reflow can be performed to help self-aligning the top semiconductor die 420 to the upper semiconductor die 418. Here, the high temperature treatment can further cure the NCF material and solder balls included in the semiconductor device assembly 400. In one example, the mass reflow process can be conducted at around 260° C. for about 10 minutes.

Lastly, the method 500 includes flowing a mold compound material into a gap between the top semiconductor die and the upper semiconductor die, at 510. For example, MUF materials 420 can be flow into the air gaps between the top semiconductor die 406 and the upper semiconductor die 418, as shown in FIG. 4G. The MUF material can surround the solder pillars and solder balls that are disposed in the air gap to provide mechanical support and enhance the adhesion between the top semiconductor die 406 and the upper semiconductor die 418. In this example, the MUF material can also be disposed above a backside surface of the semiconductor wafer 402 for encapsulation.

In some examples, the method 500 may also include inspecting the alignment of the upper semiconductor die 418 and the plurality of semiconductor dies 404. For example, after stacking the upper semiconductor die 418, an optical inspection can be conducted to exam alignment of contact pad patterns of the upper semiconductor die 418 with that of the underneath plurality of semiconductor dies 404.

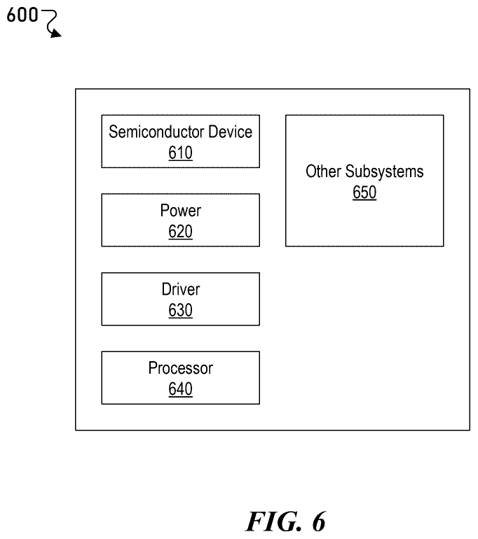

Any one of the semiconductor structures described above with reference to FIGS. 2 to 5 can be incorporated into any of a myriad of larger and/or more complex systems, a representative example of which is system 600 shown schematically in FIG. 6. The system 600 can include a semiconductor device 610, a power source 620, a driver 630, a processor 640, and/or other subsystems or components 650. The semiconductor device 610 can include features generally similar to those of the semiconductor devices described above, and can therefore include the hybrid stacking of semiconductor dies using NCF material and MUF material described in the present technology. The resulting system 600 can perform any of a wide variety of functions, such as memory storage, data processing, and/or other suitable functions. Accordingly, representative systems 600 can include, without limitation, hand-held devices (e.g., mobile phones, tablets, digital readers, and digital audio players), computers, and appliances. Components of the system 600 may be housed in a single unit or distributed over multiple, interconnected units (e.g., through a communications network). The components of the system 600 can also include remote devices and any of a wide variety of computer-readable media.

Specific details of several embodiments of semiconductor devices, and associated systems and methods, are described below. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

In accordance with one aspect of the present disclosure, the semiconductor devices illustrated above could be memory dice, such as dynamic random access memory (DRAM) dice, NOT-AND (NAND) memory dice, NOT-OR (NOR) memory dice, magnetic random access memory (MRAM) dice, phase change memory (PCM) dice, ferroelectric random access memory (FeRAM) dice, static random access memory (SRAM) dice, or the like. In an embodiment in which multiple dice are provided in a single assembly, the semiconductor devices could be memory dice of a same kind (e.g., both NAND, both DRAM, etc.) or memory dice of different kinds (e.g., one DRAM and one NAND, etc.). In accordance with another aspect of the present disclosure, the semiconductor dice of the assemblies illustrated and described above could be logic dice (e.g., controller dice, processor dice, etc.), or a mix of logic and memory dice (e.g., a memory controller die and a memory die controlled thereby).

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “top,” “bottom,” “over,” “under,” “above,” and “below” can refer to relative directions or positions of features in the semiconductor devices in view of the orientation shown in the Figures. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device, comprising:
a lower semiconductor die;
a stack of upper semiconductor dies disposed over the lower semiconductor die;
a top semiconductor die disposed over the stack of upper semiconductor dies;
a non-conductive film material disposed between adjacent semiconductor dies of the lower semiconductor die and the stack of upper semiconductor dies; and
a mold compound material disposed between the top semiconductor die and the stack of upper semiconductor dies, and on sidewalls of the stack of upper semiconductor dies and the top semiconductor die.

2. The semiconductor device of claim 1, wherein the stack of upper semiconductor dies each includes a plurality of through silicon vias (TSVs).

3. The semiconductor device of claim 2, wherein the lower semiconductor die, the stack of upper semiconductor dies, and the top semiconductor die are bonded through solder pillars and solder bumps.

4. The semiconductor device of claim 3, wherein the solder pillars and solder bumps are electrically connected to corresponding TSVs of the stack of upper semiconductor dies.

5. The semiconductor device of claim 1, wherein the mold compound material is disposed above a backside surface of the lower semiconductor die.

6. The semiconductor device of claim 1, wherein the lower semiconductor die is an interposer fabric die, and wherein the stack of upper semiconductor dies and the top semiconductor die are memory dies.

7. The semiconductor device of claim 1, wherein the stack of upper semiconductor dies includes seven semiconductor dies.

8. The semiconductor device of claim 1, wherein the non-conductive film material comprises epoxy-based materials, acrylic-based materials, and/or polyimide-based materials, and wherein the mold compound material comprises materials including an epoxy-based liquid compound with granules, an epoxy-based liquid compound without granules, a granular compound, a thin-film based underfill, a thin-film based compound, a resin-based encapsulant, and/or a polymer.

9. A semiconductor device, comprising:
a top semiconductor die;
a plurality of lower semiconductor dies that are vertically stacked and that are disposed under the top semiconductor die;
a non-conductive film material disposed between adjacent semiconductor dies of the plurality of lower semiconductor dies; and
a mold compound material disposed between the top semiconductor die and the plurality of lower semiconductor dies.

10. The semiconductor device of claim 9, wherein the mold compound material is disposed on sidewalls of the top semiconductor die and the plurality of lower semiconductor dies.

11. The semiconductor device of claim 9, wherein the top semiconductor die and the plurality of lower semiconductor dies are bonded through solder pillars and solder bumps.

12. The semiconductor device of claim 11, wherein the plurality of lower semiconductor dies each includes a plurality of through silicon vias (TSVs).

13. The semiconductor device of claim 12, wherein the solder pillars and solder bumps are electrically connected to corresponding TSVs of the plurality of lower semiconductor dies.

14. The semiconductor device of claim 9, wherein the top semiconductor die is thicker than each one of the plurality of lower semiconductor dies.

15. A method of forming a semiconductor device, comprising:
stacking a plurality of lower semiconductor dies on a first semiconductor wafer;
performing an intermediate thermal treatment on the stacked plurality of lower semiconductor dies;
collectively bonding an upper semiconductor die above the plurality of lower semiconductor dies through performing a thermal compression bonding (TCB) treatment on the upper semiconductor die and the plurality of lower semiconductor dies;
stacking a top semiconductor die above the upper semiconductor die using a flux-less TCB bonding process and performing a mass reflow process; and
flowing a mold compound material into a gap between the top semiconductor die and the upper semiconductor die.

16. The method of claim 15, wherein each of the plurality of lower semiconductor dies and the upper semiconductor die has a layer of non-conductive film material disposed on its frontside surface.

17. The method of claim 16, further comprising:
laminating a non-conductive film on a frontside surface of a second semiconductor wafer; and
singulating the second semiconductor wafer and the non-conductive film to form the plurality of lower semiconductor dies and the upper semiconductor die, each of the plurality of lower semiconductor dies and the upper semiconductor die including a corresponding layer of non-conductive film material.

18. The method of claim 15, wherein the intermediate thermal treatment can be conducted at around 140° C. for one to two seconds, and wherein the TCB treatment can be conducted at a temperature ranging from 330° C. to 380° C. for ten seconds to twenty seconds.

19. The method of claim 15, wherein the mass reflow process can be conducted at around 260° C. for about 10 minutes.

20. The method of claim 15, wherein the flowing of mold compound can be conducted at a temperature ranging from 110° C. to 190° C. for a period of 30 minutes to 90 minutes.
